(19) United States
(12) Patent Application Publication
(10) Pub. No.: US 2005/0052252 A1
(43) Pub. Date: Mar. 10, 2005

(54) Synchronizing unit for redundant system clocks

(76) Inventor: Joseph F. Galibois, Bedford, NH (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 10/891,886

(22) Filed: Jul. 15, 2004

Related U.S. Application Data
(60) Provisional application No. 60/487,499, filed on Jul. 15, 2003.

(51) Int. Cl. H03L 7/00

(52) U.S. Cl. 331/25

(57) ABSTRACT

Phase detecting and alignment of an active and a back-up clock are provided by a detector and controller. Two delay lines of differing resolution function to delay the clock and are themselves controlled to minimize or substantially eliminate the phase drift between the back-up clock from one timing module and the main clock from another timing module. In particular, both a coarse delay line and a fine delay line are adjusted based on set thresholds that are used to determine the direction of the necessary phase correction for each of the delay lines. In one particular embodiment, the coarse delay line governs the gross phase adjustments which propagate through the timing module and are, in turn, utilized to make finer adjustments to the fine delay line and achieve minimal phase delay between the main clock and the backup clock.

This application claims priority from Ser. No. 601487,499, filed Jul. 15, 2003, the entire contents of which are incorporated by reference herein in its entirety.

### BACKGROUND

1. Field of the Present Invention

The present invention relates to synchronizing clocks and, more particularly, to synchronizing clocks in order to minimize and substantially eliminate the phase drift that arises between the clocks.

The present invention is applicable to any process or device for the synchronization of clocks. However, since the invention has a particular market applicability, it is appropriate to discuss the invention in terms of an industry-accepted clock synchronization schema. One such schema is known as the GR-1244-CORE criteria.

2. Related Art

The GR-1244-CORE criteria, formulated by Telcordia (formerly Bellcore), sets forth a recommended schema for “Clocks for the Synchronized Network: Common Generic”. This schema is the authority on system design within the US for equipment that is to be used in public telephonic carrier networks. The GR-1244-CORE is comparable to the ITU G.781, G.810, G.811 and G.812 standards, but the GR-1244-CORE specifies a complete package of details that provide for all of the equivalent ITU systems rolled in to one. Due to this and the industry success of the GR-1244-CORE criteria, this criteria has become the de facto standard. The de facto standard is so popular that most customers are not interested in products that are not substantially GR-1244-CORE compliant.

More particularly, the GR-1244-CORE requires that the redundant synchronized clocks in a Network Element have a Synchronizing Unit to maintain precise frequency synchronization between a back-up clock and an active clock. The characteristics of the Synchronizing Unit will be better understood with reference to FIG. 1. FIG. 1 illustrates a conceptual block diagram of clocks embedded in a Network Element (NE) 100. An active clock 102 and a back-up clock 104 are illustrated generally by the dash-lined boxes located atop one another. Each clock includes an input control, 106 and 108 respectively, for controlling the input and a sync unit 110 and 112 respectively, for synchronizing the clock signals between the active and back-up clocks. The synchronized clocks are multiplexed by a multiplexer 114 and the output thereof is forwarded to a Network Element function 116.

In operation, a line timing mode signal 118 (or any Synchronization Input) is input to the Network Element 100 and feeds the primary (PRI) and secondary (SEC) clock signals of the active and back-up clocks 102 and 104 respectively. Additional block functions 120 may be used to alter the signal format of the line timing mode signal 118. Upon synchronization of the clocks, there may also be additional functionality 122 included within the NE, for example, an alarm or an off-site (OS) function.

GR-1244 leaves the method of clock signal synchronization up to the individual equipment providers. In other words, the telecommunications service provider, or carrier, is left to the task to construct the synchronizing units themselves. Although the solutions provided to date have yielded frequency aligned clock signals, they have altogether overlooked the problem that the clock signals tend to drift apart in phase. Most off-the-shelf timing modules do not provide a way to keep the output of one timing module precisely phase synchronized to the output of another. Indeed, the phase drift may be so severe in some cases that the clock signals may deviate as much as ½ UI (unit interval or one clock period) of the output. That is not to say that phase drift is limited to GR-1244 applications. On the contrary, phase drift can, and does, occur in any set of clocks that are to be synchronized. Until now, there has been no easily implemented solution that addresses the problem of phase drift between synchronizing clocks. Thus, a simple solution that compensates or minimizes, and in fact substantially eliminates, the phase drift between synchronizing clocks is needed. In particular, a solution within a GR-1244 compliant system is needed to synchronize the phases of the system clocks.

### OBJECTS & SUMMARY OF THE INVENTION

An object of the invention is to provide synchronization of clocks.

An object of the invention is to provide a solution to synchronizing clocks as a wrap-around to existing technology.

An object of the invention is to provide synchronization of clocks in compliance with the GR-1244-CORE criteria.

An object of the invention is to minimize and substantially eliminate phase drift between synchronized clocks.

An object of the invention is to provide delays to delay the clock signal to eliminate the phase drift.

An object of the invention is to provide a fine delay situated after the clock and a coarse delay before the clock.

An object of the invention is to adjust the fine delay by adjusting the coarse delay and allowing the delay to propagate through the clock.

An object of the invention is to indicate a lateness of the clock signal to be aligned.

In at least one aspect, the present invention provides a phase detector and controller along with electronic delay lines that minimize or substantially eliminate the phase drift between the back-up clock from one timing module and the main clock from another timing module.

The phase detector may be, in one aspect, an FPGA-type phase detector. The phase detector itself may be implemented using a flip-flop. In this case, a possible arrangement may be to arrange the clock pin of the flip-flop to be driven by the clock from the back-up clock. Further, the data pin of the flip-flop may be arranged to be driven by the clock from the main clock.

In yet another aspect, the output of the flip-flop may be assigned a status, rather than a value. The output of the flip-flop, for example, may be a signal designated as LATE, signifying a ‘late’ status.

The output of the flip-flop, in another aspect, may be filtered for metastability. This may be done, for example, by cascading the output of the flip-flop through a series of flip-flops to squelch any metastability.

In a still further aspect, the stabilized signal is then sent to a device, such as an integrator, to determine the amount of ‘late’-ness observed over a period of time.

In one possible arrangement, two thresholds may be used to determine if the integrator value indicates that the back-up clock is ‘late’, ‘not late’ or ‘in phase’. If the lower threshold is not met, the back-up clock is not late at all (e.g., early) and should be delayed more. If the lower and upper thresholds are both met, the clock is consistently late and should be advanced. If the lower threshold is met and the upper threshold is not, the back-up clock is ‘in phase’ with the main clock and its current delay should be maintained.

The delay lines previously mentioned are used in one arrangement to delay and advance the back-up clock as it tracks the main clock. In one variation, the delay lines affecting the main clock are ‘centered’—i.e., brought to their middle (or half-way) value. The delay lines of the back-up clock are adjusted in a manner determined by the output of the phase detector. One of the delay lines may be a fine delay line, for example having tunable increments <<0.01 UI, that delays the signal exiting the timing module. The other delay may be a coarse delay line, for example having tunable increments >0.01 UI, that delays the reference signal that feeds the timing module.

In a possible method for controlling the delay lines the coarse delay line is adjusted in the direction of the threshold that was met when the fine delay line reaches one of two pre-determined values. The coarse delay change propagates through the timing module and is utilized to move the fine delay line from its threshold value towards a more advantageous value. When the coarse delay line reaches one of two threshold values, the reference clock through it is adjusted coincidentally with a commensurate change in the coarse delay toward a more advantageous value.

It shall be appreciated that the invention maintains the back-up clock in phase with the main clock indefinitely.

### BRIEF DESCRIPTION OF THE DRAWINGS

The present invention shall now be described with reference to the following figures in which the same reference numerals refer to like components.

FIG. 1 illustrates a network element according to the GR-1244-CORE;

FIG. 2 illustrates a clock timing diagram;

FIG. 3 illustrates a prior art Phase Detector;

FIG. 4 illustrates the synchronizing unit according to one embodiment of the present invention;

FIG. 5 illustrates a schematic diagram of the phase checker module according to one embodiment of the present invention; and

FIG. 6 illustrates a controller according to one embodiment of the present invention

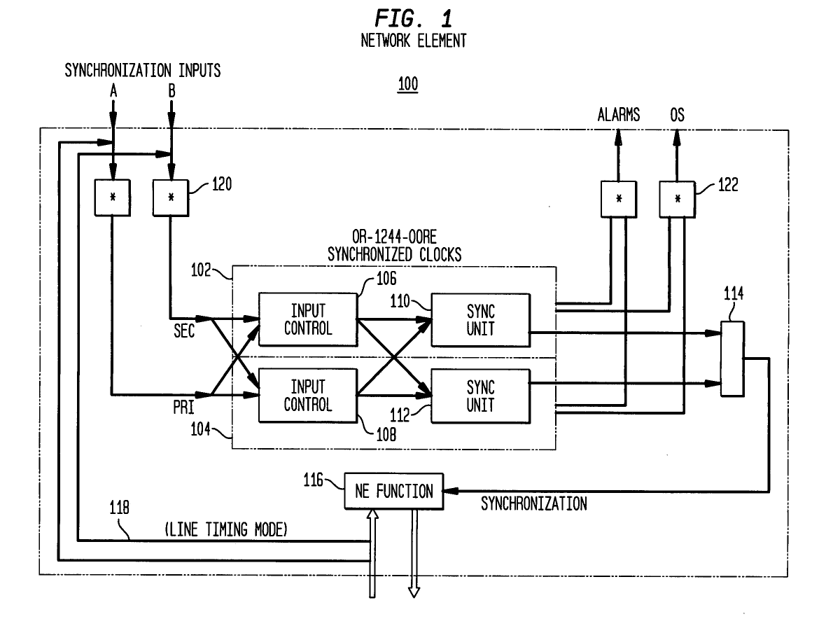

### DETAILED DESCRIPTION OF THE PREFERRED EMBODIMENTS

As previously discussed, the desired goal is to phase-align one clock to another even though these clocks may be frequency-matched to the same reference. The situation will be better understood from the timing diagram of

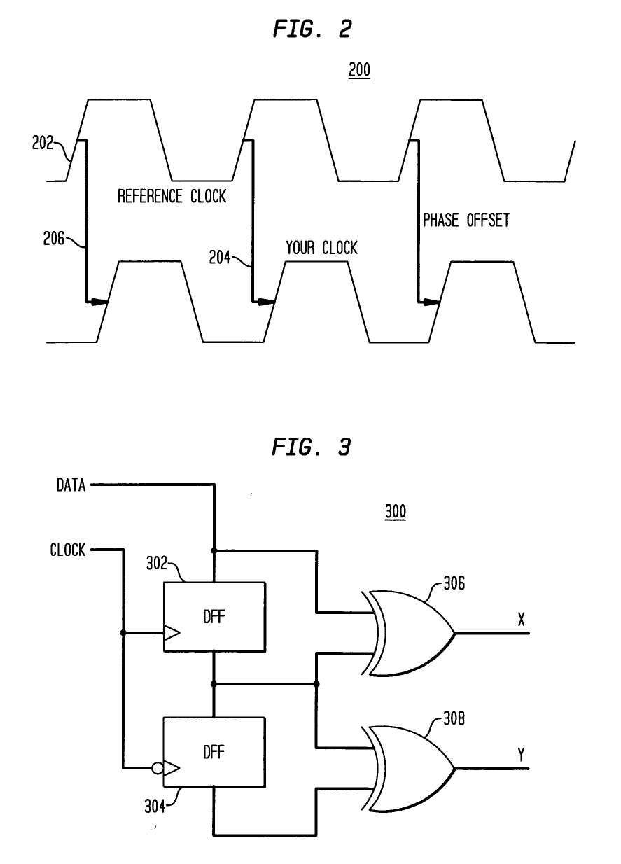

FIG. 2 which illustrates that a clock 202 may be in frequency alignment with a reference clock 204 but there is a phase difference 206 (which amounts to a timing delay) between these clocks 202 and 204. In resolving this problem it would be advantageous to utilize the existing phase-locked-loop generating the clocks. This would also suit the existing architecture specified by the GR-1244-CORE criteria.

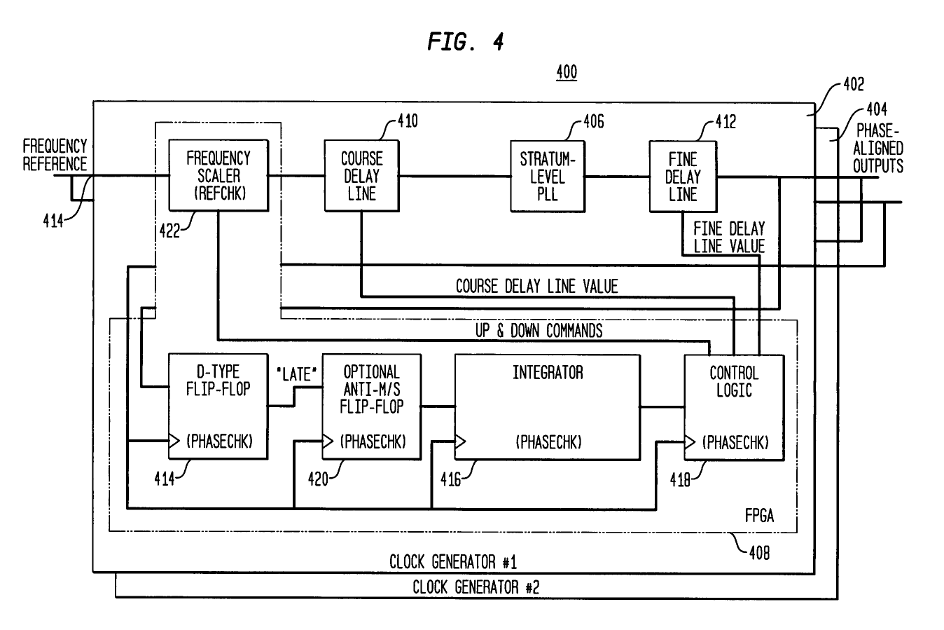

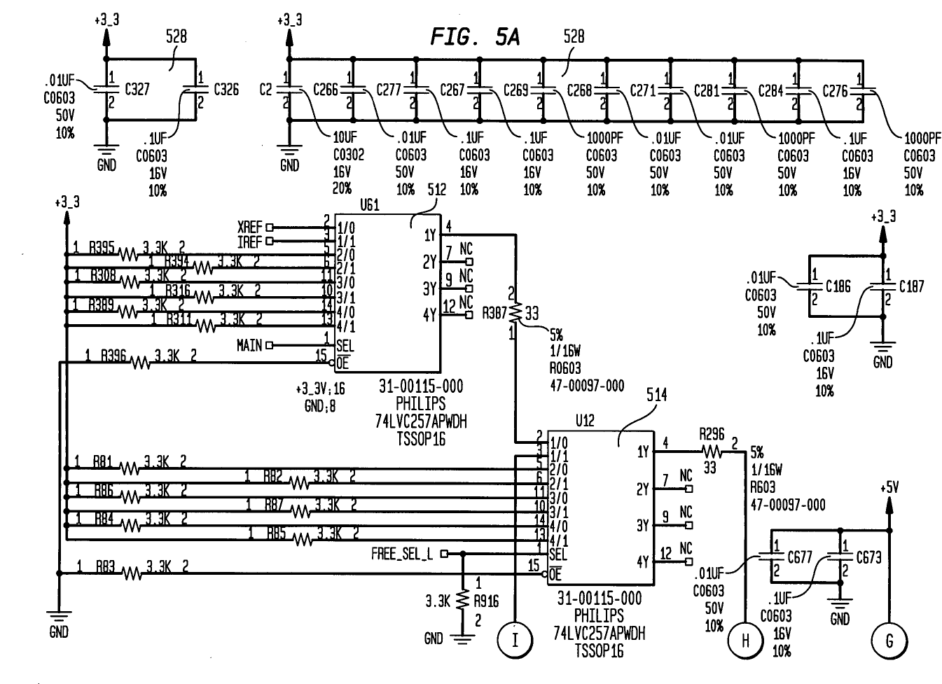

A standard phase detector, such as the HOGGE phase detector illustrated in FIG. 3, is one type of phase detector that has been applied to correct the clock phase differences. The HOGGE circuit 300 shown in FIG. 3 includes two D-type flip-flops 302, 304 coupled in an arrangement with Exclusive-OR Gates (XOR) 306 and 308.

In operation, the HOGGE phase detector samples the input data at the rising edge of the clock signal by the first flip-flop 302. The second flip-flop 304 samples the output of the first flip-flop 302 at the falling edge of the clock. Then, the three sample points are passed to the two XOR gates 306, 308 to generate the control signals X and Y. The phase error is shown in the difference between the duty cycles of X and Y. Phase lock occurs when the clock signal rises at the middle of the data pulse, so that X and Y have equal duty cycles. Although, the control mechanism is improved because X and Y express the phase difference linearly, they toggle on and off alternately at lock. Therefore, rippling is a problem in this design.

Further, the HOGGE circuit suffers from further disadvantages. The HOGGE phase detector requires analog circuitry to evaluate and react to the phase information. Since analog elements are subject both to degradation over time to physical dissimilarities, providing for a consistent and easily reproduceable design of such a phase detector has been difficult. Finally, the HOGGE phase detector is also limited in its phase locking ability in that it is designed for scenarios in which the data rate is at least half that of the clock. However, in many situations this is not the case.

The Sync Unit solution 400 provided by the present invention is shown in FIG. 4. An active clock 402 and a back-up clock 404 are illustrated as cascaded clock generators 1 and 2, respectively. The clock signal from each of the clock generators 402, 404 is supplied by a phase-locked-loop 406, which may advantageously be part of the existing GR-1244-CORE architecture. In the present invention, there is provided a phase detector 408, indicted by the hatched line that controls a coarse delay line 410 and a fine delay line 412. According to one particularly preferred embodiment of the present invention, the coarse delay line 410 is placed before the phase-locked-loop 406 to delay the frequency reference clock 414. In this embodiment, the fine delay line 412 is placed after the phase-locked-loop 406 in order to delay the output. The output of the fine delay line represents the active clock signal.

As previously indicated, the invention cascades the clock generators 1 and 2 (402, 404). In the particular embodiment shown in FIG. 4, the output of the first clock generator 402 drives the timing of the phase detector 408 of the first clock generator 402. Further, the output of the second clock generator 404 is the data input of the phase detector 408. Similarly, the clock output of the second clock generator 404 drives the timing of the phase detector of the second clock generator 404 and the output of the first clock generator 402 supplies the data input for the phase detector of the second clock generator 404. In this manner, each clock generator, 402, 404, phase detects and controls its own clock to be aligned with the clock of the other clock generator.

It shall be appreciated that the present invention does not necessarily need to include cascades clock generators. The invention may comprise a single clock generator that inputs the clock to be aligned as the timing signal for the phase detector 408 and utilizes an arbitrary back-up clock input for the data input of the phase detector 408.

Now turning to the phase detector 408 in more detail, an exemplary arrangement shown in FIG. 4 includes a flip-flop 414, which may be of the D-type variety, a device for detecting lateness 416 and control logic 418. The device for detecting lateness in the exemplary arrangement may be a device that detects whether the signal to be aligned is early, in-phase or late with respect to the input clock. Further, the device for detecting lateness may be an integrator that determines lateness over a period of time.

Optionally, there may be a device 420 for removing metastability, such as a series of sequential flip-flops. Metastability can occur in devices such as a flip-flop used in the exemplary embodiment 414 owing to the characteristics of such devices. While not particularly part of the phase checker 408, FIG. 4 further illustrates that there may also be provided a frequency scaler (reference checker) 422 for scaling the input reference clock to the particular phase-locked-loop 406.

The output of control logic 418 controls the delay lines 410, 412 in order to adjust the delay of the phase-locked-loop 406. It shall be appreciated that the exemplary arrangement shown in FIG. 4 situates a coarse delay line 410 before the phase-locked-loop and a fine delay line 412 after the phase-locked-loop. In this manner the invention could be considered to “wrap around” an off-the-shelf clock generator. In other words, the present invention utilizes the state-of-the-art clock devices, such as those recommended by GR-1244-CORE, and integrates well with the existing technology. Thus, in addition to providing precise phase alignment, the present invention provides an easily designed solution that solves the phase synchronization problems inherent to current clock generators.

Based on the output of the integrator 416 that indicates whether the clock to be adjusted is late, early, or in-phase, the controller 418 adjusts the coarse delay and fine delay lines 410, 412 in such a manner that minimizes, or otherwise substantially eliminates, the phase difference between the clock generators 402, 404. The delays may be adjusted on the basis of predetermined thresholds. For example, if a lower threshold is not met, the back-up clock is not considered late at all and should be delayed more. If the lower and upper thresholds are both met, the clock is consistently late and it should be advanced. If the lower threshold has been met and the upper threshold has not, the back-up clock is ‘in phase’ with the main clock and its delay should be maintained. Contrary to the typical operation and the manufacturer's prohibitions, the goal is to keep the clock-data relationship at the flip-flop inside the flip-flop's setup-hold window.

Two delay lines are used to delay and advance the back-up clock as it tracks the main clock. The delay lines affecting the main clock are ‘centered’ (i.e., brought to middle or halfway values). The delay lines of the back-up clock are adjusted in a manner determined by the phase detector described above. A fine delay line (for example, adjustable in increments <<−0.01 UI) delays the signal exiting the timing module. The coarse delay line (for example, adjustable in increments >0.01 UI) delays the reference signal that feeds the timing module. When the fine delay line reaches one of two pre-determined values, the coarse delay line is adjusted in the direction of the threshold that was met. The coarse delay change propagates through the timing module and is used to move the fine delay line from its threshold value towards a more advantageous value. When the coarse delay line reaches one of its two threshold values, the reference clock through it is adjusted coincidentally with a commensurate change in the coarse delay toward a more advantageous value. This process provides the back-up clock the ability to stay in phase with the main clock indefinitely.

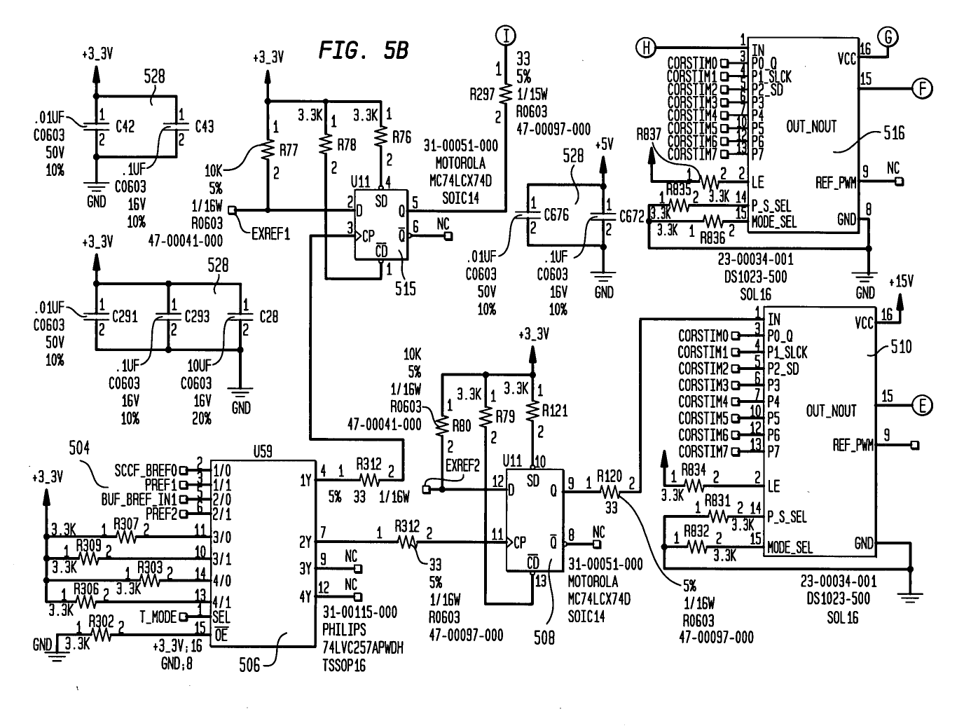

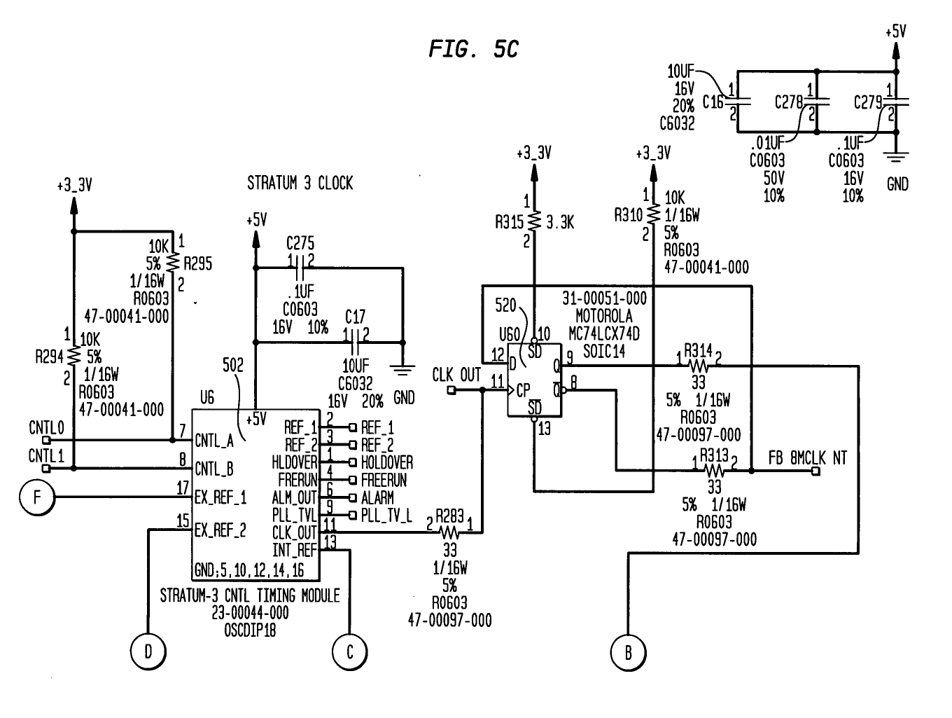

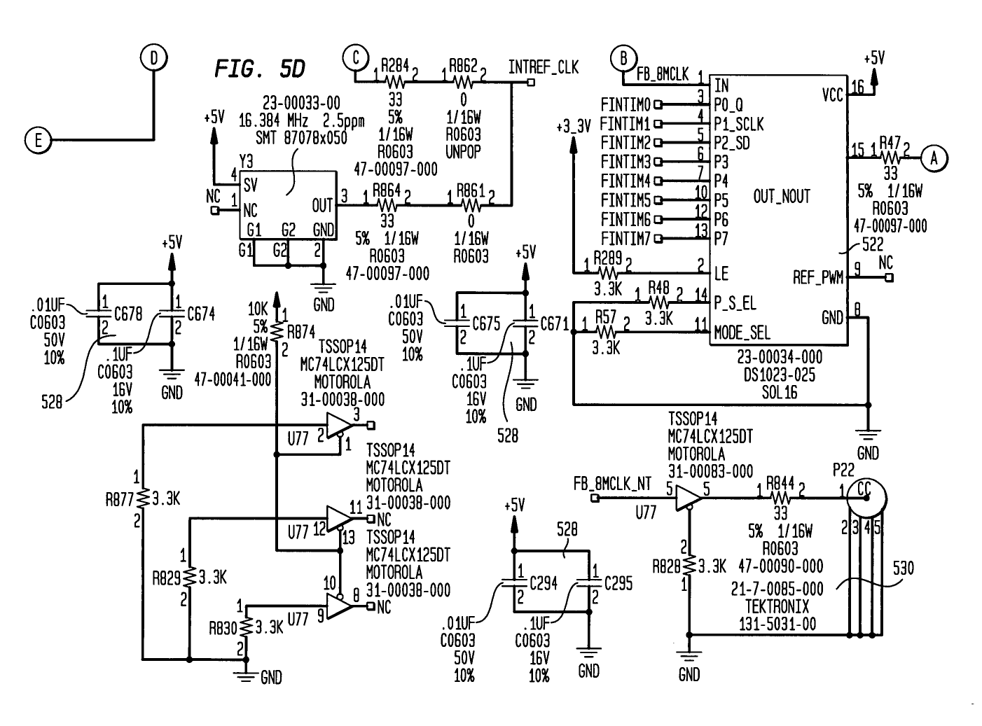

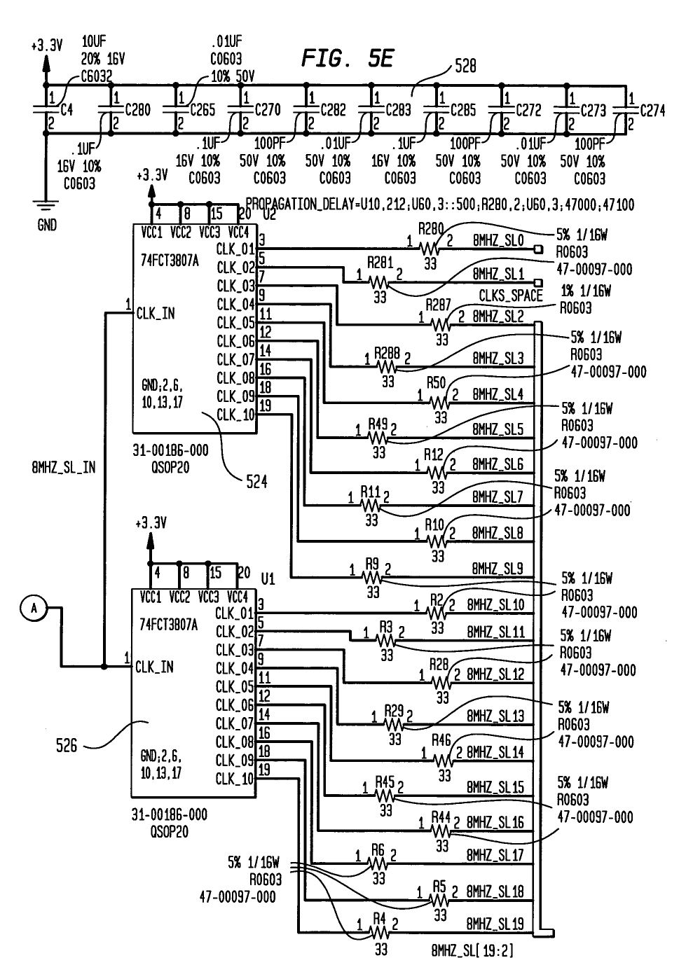

An exemplary implementation of the invention is set forth as a schematic 500 diagram in FIG. 5. Of course, the illustrated schematic is exemplary and the particular circuitry or components may be specific to this implementation such that the invention may be practiced by another circuit than that shown. Rather than discuss the individual signals of each component, it is perhaps more helpful to discuss the functionality of each component with reference to the more relevant signals. The details of the circuitry will be readily understood by those skilled in the art and, in any event, are clearly demonstrated in the schematic.

Centrally located in the illustrated schematic is shown a clock 502, which may be a phase-locked-loop, such as an off-the-shelf stratum-3 clock. In a preferred aspect, the invention is said to wrap around the clock 502, providing logic and control for phase checking and phase alignment of the main and back-up clocks.

Reference signals 504 are input to circuit 500, which may include either or both of a line timing and/or external timing reference clock. The reference signals are multiplexed by a multiplexer 506 to select either the line timing or the external timing to be used to clock a flip flop 508. The flip-flop 508 re-clocks the references from the control logic (418, FIG. 4) with the original reference signals used to generate those references. The references are originally, for example, 1.544 MHz or 2.048 MHz, and are scaled to, for example, 8 KHz. This removes substantially most of the jitter introduced into the reference signals caused by the scaling operation (422, FIG. 4).

To continue, a delay 510, such as a digital delay line, digitally sets a coarse delay for the input reference signal based on a coarse delay signal. Here, the delay signal is shown as an 8-bit signal. The delayed reference signal is input to the clock 502.

In practice, there may occur an instance where there is no reference signal. In this case, the present invention may provide a manner in which to generate an internal reference. In the exemplary case, there is provided, for example, a series of multiplexers 512, 514 to multiplex a crossed over timing signal or an internal timing signal. The second multiplexer 514 further allows a freely selectable timing signal to be selected. Of course, these timing signals are exemplary and the invention may provide any reference signal.

Similar to the flip-flop 508, flip-flop 515 re-clocks the references from the control logic (418, FIG. 4) with the original reference signals used to generate those references. This removes substantially most of the jitter introduced into the reference signals caused by the scaling operation (422, FIG. 4).

To continue, whichever reference signal is selected by multiplexer complex 512, 514, is delayed by a coarse delay 516, which may be an analog delay line or a digital delay. The delay 514 is controlled to delay the selected reference signal by coarse increments (or decrements) in a similar fashion as the delay 510. The delayed signal is then sent to the clock 502. A control signal (CTRL A, B) 518 indicates which reference signal is to be used by clock 502, e. g., either the external reference signal supplied from delay 510 or the internally generated reference signal from delay 516. Again, the provision of an internally generated reference signal is optional and may, be arranged in another manner. For example, the reference signal passed through delay 516 might be an external reference as well. In this case, the internally generated reference is injected by the multiplexer as a matter of practicality.

The clock 502 then generates a clock based on the delayed reference signal. The generated clock signal is then forwarded to the fine delay 522. Before this, however, the invention may provide a frequency scaler, such as the flip-flop 520 shown, which scales the frequency of the clock signal. This is done in the exemplified schematic in order to accommodate particular signalling characteristics of the on-board components and is optional depending on the on-board specific needs.

Returning now to the fine delay, there is provided another delay 522, that is controlled to delay the generated clock signal by fine increments (decrements) according to a control signal. Again, the control signal is shown as an 8-bit control signal.

In the case that the clock 502 fails to provide a precise, local timebase signal for use by the controller, which may occur in practice, there is optionally provided a stand-by oscillator 528 that generates that signal. The stand-by clock signal generated therefrom may be voltage controlled by components such as the resistors shown in FIG. 5.

The clock signal generated, and subsequently delayed, is then forwarded to fan-out buffers 526, 524, which distribute the delayed clock signal. As discussed, the delays are controlled according to the invention in order to phase align the clock with a clock from another clock generator. This phase aligned clock signal is distributed by the fan-out buffers 526, 524 to various destinations, such as different circuit cards, etc.

There may be provided decoupling capacitors 528 that are situated with respect to other components that ensure proper device operation and signal integrity. These capacitors are optional and it is a design choice where they are situated. In FIG. 5, one possible selection of such decoupling capacitors is shown.

A further option may include providing a testing capability. In the exemplary schematic shown, an amplifier 530 provides an amplified signal suitable for test purposes. A test port, for example, may be included in the amplifier circuitry for providing a convenient manner in which to sense the amplified signal using testing equipment.

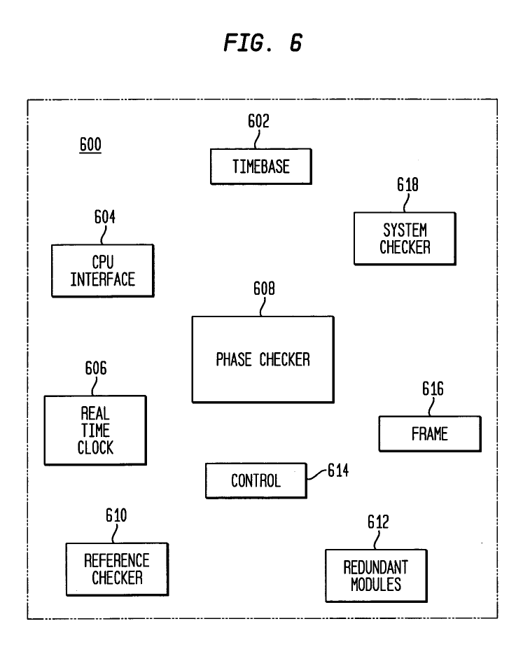

In the particularly preferred embodiment provided herein, a field programmable gate array (FPGA) is provided as part of the overall circuit card, of which, the circuit of FIG. 5 is only a portion. FIG. 6 shows in general, a block format the overall functional architecture of the clock and timing circuit card which includes phase checking circuitry provided in the circuit of FIG. 5 and functional diagram of FIG. 4. Although the primary function of the FPGA is to provide overall control functions to the circuit card via control module 614, the remaining portions of the FPGA generally function as provided below. Appendix A shows one particular embodiment of the software logic, in HDL format, programmed within the phase checking module within the FPGA.

A clock controller 600 will now be described with reference to FIG. 6 that provides the clock and control signals for the exemplary schematic shown in FIG. 5. In essence, the clock controller 600 provides the phase difference checking and adjustment control of the delay lines for adjusting and aligning the phase of the clock signals. The clock controller 600 will be described in terms of functional modules that provide the various control signals. Of course, the particular architectures illustrated in FIGS. 5 and 6 are exemplary and the specific signal assignments and arrangements of the components may be modified within the scope of the invention. One skilled in the art will readily understand how to implement these modules using known software and/or hardware technologies.

In the exemplary clock controller, there are provided internal clocks employed to drive the internal components. For example, the timebase 602 module generates internal clocks. An SEC_TICK signal, for example, may provide a 62-ns pulse that occurs every second. An SEC_CLK may provide a 1-Hz clock with 50% duty cycle. An XTICK may provide a 62-ns pulse that occurs every 100 ms. These internal clocks may, of course, be different depending on needs of the particular circuit board.

A CPU interface module 604 comprises a CPU interface. In one aspect, the interface is an eight-bit data bus, a five-bit address bus and miscellaneous interface control signals that allow a CPU to provide provisioning and control information, as well as to extract status information. The exchange of information takes place within registers inside the CPU interface module. Control signals to various other modules inside the chip, as well as control signals that leave the chip, emanate from read/write registers within the CPU interface. Status signals congregate at read-only registers within CPU interface. The CPU interface may also act as the interrupt controller for CPU interrupts that originate within the CCF.

The invention may also provide a debugging and testing capability. For example, the CPU interface 604 may provide override values to the phase checker 608, so that the controller fine and coarse values can be overridden.

A real time clock 606 may provide a proprietary real-time clock. Here, software needs a persistent sense of date and time, but the real time clock within the CPU was reset during a soft reset, losing its information. The real time clock, may for example, not be reset except at board power-on. The real time clock may also generate a delayed IO enable signal, which is used to gate outputs soon after chip power-on until they are stable.

The phase checker module 608 checks the phase difference of the clock signals. This information is integrated over a period at which time a decision is made to increase or decrease the delay of the local clock path. In the case of the master clock, the delay lines are centered, since it is the slave clock that is to be phase aligned. Of course, the invention may phase align the master, slave, or both.

When the fine delay value approaches its maximum or minimum value, an appropriate coarse delay adjustment is made. The coarse delay adjustment (which may be made to the input of the stratum module) eventually propagates through the stratum module and (generally) moves the fine delay line away from its threshold. Coarse adjustments are recommended not to occur earlier than a predetermined time after the previous coarse adjustment.

When the coarse delay value approaches its maximum (or minimum) value, representing a worse case scenario that cannot be normally adjusted through delays, there is a solution provided by the invention. This may be an adjustment of the clocks, colloquially referred to as a “whack.” One manner in which to implement the whack is to toggle the coarse delay line from, for example, a high limit to a low limit, or vice versa, depending on which limit it was approaching while also adjusting the frequency of the scaled reference being sent to the slave clock. Since it is considered rather extreme to force a frequency adjustment to a clock, “whacks” should be rarely employed in the real world. It is suggested to compensate for such a whack by performing the toggle simultaneously with an absorption of the same amount of phase into the clock reference that is being sent to the stratum module.

The exemplary aspect may further provide one or more reference checkers to check an incoming reference signal (for example, a 1.544-MHz clock, or a 2.048-MHz clock) and generate an appropriate reference signal, such as 8-kHz, for the stratum module. References are monitored for activity and frequency and (where applicable) for lack of line error. The degrees of quality of the clock are sent to the controller, which makes clock selection decisions based on signals from the relevant reference checker. In FIG. 5, this is performed using the multiplexers 506, 512, 514.

In a further aspect, the phase checker is not directly involved in the generation of references for the stratum module. In this case, the whack may be executed by sending an appropriate whack command (UP_CMD or DOWN_CMD, see Appendix) to reference generator modules. The reference generator module that responds to the command sends back an acknowledgement (ACK_CMD). Each reference checker is capable of receiving a whack command (UP_CMD or DOWN_CMD) from the phase checker and transferring the requested phase adjustment into the reference it is generating.

Returning now to the clock controller 600, there may also be provided a module 610 to determine which card is the main/active/master card. The back-up/stand-by/slave card is the card that is not chosen.

A control module 614 may act as the central controller for the clock system. A function of the control module 614 may be to determine which references should be sent to the stratum module, which reference the stratum module should be using as a primary reference, or which clock mode the stratum module should be using. Based on its knowledge of the active references, the control module also channels acknowledge (ACK) and (SAFE) signals among the reference checker modules and the phase checker 608.

A frame module 616 may be provided to generate frames, such as a 62-ns pulse every 125 us. This signal may be created simply by counting clock cycles when the board is the main clock. When the board is not the main clock, its frame output is enslaved to that of the main card. The frame module may also generate a non-frame signal (emarf, see Appendix), that is guaranteed to be out of phase with the normal frame pulse. This non-frame signal may be a 62-10 ns pulse every 125 us, for example.

There may also be provided a manner of checking system parameters using a system checker module 618. The assessment of these parameters may be used by module 612 to decide which card is the main card.

An exemplary hardware description language (HDL) listing for generating the phase checker (408, FIG. 4) is set forth in the Appendix. The provided HDL is in the Verilog description language, but may be written in another HDL language. At any rate, it is fruitful here to discuss the logic of the phase checker HDL. This logic may, of course, be formulated in another manner than that set forth.

After the declaration section, there is provided the integrator logic. The integrator logic determines whether the clock signal of the relevant clock generator is late or early with respect to the referenced clock of the other clock generator. In this case, the integrator logic performs the integration using counters that are incremented over time when these late or early conditions are met. The counters effectively sum up the instances when the clock is late, or early, indicating an overall “lateness” or “earliness” of the clock.

The next block of logic evaluates the output of the integrator using low and high thresholds. When the clock is late for more than a certain time, then the low threshold is met. Otherwise, the low threshold is set as not being met. When the clock is late for an even longer time, then the high threshold is met. Otherwise, the high threshold is set as not being met.

Based on these low and high thresholds, the next logic block actuates the controller (418, FIG. 4). The state machine for the controller that decides how to control the delays is set forth in the next logic blocks. The states of this state machine or the particular logic flows set forth are exemplary and may be practised in another manner than that presented in the Appendix.

At the outset, the state machine defines default assignments for the parameters, aligned, up command, down command, fine delay and coarse delay, which will be explained in more detail. These defaults reserve for Verilog the corresponding components upon build time of the schematic (FIG. 5, for example) and may be an optional HDL design.

The next logic block allows non-standard assignments to the delay values, wherein the invention directly overrides the present delay values when enabled to do so, or in order to complete a whack. As previously discussed, the whack should be a relatively infrequent practice since this action could cause an abrupt change in the system—possibly having disruptive systematic effects. The SAFE signal indicates when it's ‘safe’ to make a large adjustment to the coarse delay line—either by overriding the coarse value or by toggling the coarse value to it's whack value. SAFE solves an implementation problem arising from properties of the selected delay lines and the scaled reference. The reference generators determine SAFE, because they know when the coarse delay lines contain high or low signals.

In this particular HDL listing, the state machine performs a whack by transferring delay, which is completed by setting the coarse delay (CDELAY) to the appropriate whack toggle value—(either h50 or h80) after it has been ascertained that the active reference generator has responded to the present command. In distinction, Coarse override (fine override), which are also listed here, cover an abnormal testing-situation. Whack is utilized for the proper normal operation of the machine.

The next logic block of the state machine increments counters in accordance with a local clock (MSECTICK), which is set here to each 100-millisecond tick of the local clock. Next, these counters are evaluated to determine whether sufficient time has elapsed to perform the next operation. In the real world, where circuit components have physical characteristics, the logic should be performed only as fast as the elements will allow, given physical characteristics, impulse responses, etc. Each operation (whacking, master centering, coarse delay adjusting and fine delay adjusting) are given predetermined set times in order to allow the system to absorb the previous change.

The next sections of the HDL for the phase checker can be described as the normal operation of the state machine, which comprises four states. The first state is the Master state. Master and slave are relative concepts in this context and either clock generator may be slave or master. In the instant example, when the state machine is indicated that it is the main/master/active clock, it normalizes, that is centers, the delay lines for the master clock. In this example, the delay lines are centered at h80. The steps it takes to center the delay values are paced by the occurrence of the MOK signal. Should override be enabled, the state machine makes no attempt to center the delay values.

It should be noted that if a command is still pending when the state machine enters the Master state from the Slave, it restrains itself from normal master operation until the action is completed. The state machine remains in the master state until ordered that it is no longer the main/master/active clock. At that time, it transitions to the Slave state. This is described in more detail with reference to FIG. 4.

The second state is the slave state. In the slave case, in contrast to the master, the slave delay lines are adjusted so that the generated clock is phase aligned with the masters. The state machine transitions to the master state when it is indicated that it is the main/master/active clock by setting the next state (NEXT_STATE) to the master. As discussed, there may be an override, here enabled by the EN_OVRD signal. There may also provided an enable, which enables the slave tracking function that tracks the phase alignment using an enable signal (ENA_CTL).

When the slave tracking function is enabled (and there is no override), the slave tracks the phase detector. Actions within the Slave state are restricted to occur only at the point of time indicated by EMARF. When these conditions are satisfied, the exemplary invention is ready to track the slave clock. Here, the slave tests whether the low threshold and high thresholds are met and therefrom determines whether the slave clock is below the lower threshold, above the high threshold, or in the middle. In this example, lower than the low threshold means that the slave clock is not late at all, i.e., early. Higher than the high threshold means that the slave clock is late. In the middle means that the slave clock is in phase.

When the phase of the slave clock is late, then the next state (NEXT_STATE) of the state machine is set to a down delay (DELAY_DN), wherein the delays are adjusted downward in order to alleviate the delay in the slave clock signal.

When the slave clock is in phase, the next state is again set to the slave state in order to continue tracking the phase. When the phase is early, then the next state is set to delay up (DELAY_UP) in order to increase the delay since the slave clock is ahead of phase.

The manner in which the coarse and fine delays are adjusted according to the example in the Appendix shall now be discussed with reference to the delay up and delay down states. In the third state, the delay up state (DELAY_UP), the fine delay is incremented and, as a further option, it is determined whether it is appropriate to perform a fine delay adjustment as determined by the FOK signal. In the case that a fine delay has become relatively large (e.g., between hFF and hA0), then a coarse delay change is effected. Optionally, it is checked that a coarse delay is appropriate using the coarse ok signal (COK). When it is determined that a coarse delay is appropriate, for example when the coarse delay is reached, then the frequency of the slave clock is reduced (FREQ_ADJ_DN). Afterward, the state machine returns to the Main or Slave state as the present state—as determined by the MAIN signal.

The fourth state, the delay down state (DELAY_DN) in the instant example, is similar to the delay up state. In this state, the coarse delay is decremented when the fine delay is determined to be relatively small. When the coarse delay is determined to be relatively small, then the frequency of the slave clock signal is adjusted upwards. When further adjustments are necessary, the state again executes the slave state. Afterward, the state machine returns to the main or Slave state as the present state—as determined by the MAIN signal.

The next section of the HDL relates to clocking operations. The first logic block, resets the control parameters. Next, the state machine sets the parameters to their normal assignments. The logic block appearing at the end of the HDL generates the flip flop of the phase checker, such as the flip flop 414 shown in FIG. 4. It should be noted that many excursions could be made from the Slave state to either the Delay Up or Delay Down state with no change to the delay values—should FOK, COK or WOK not be set.

As a design option, it shall be appreciated that the HDL set forth in the Appendix executes the decisions before the commands are carried out, thereby ensuring that decisions are not held up by command operations.

Now with particular reference to the HDL in the Appendix, the operation of the state machine of the phase checker will be discussed. Although references to specific components and values for the parameters are mentioned, the present invention may encompass other components and values other than those specified here.

The phase checker state machine checks the phase difference of the clock signals. This may be done using a flip-flop to obtain a precise, instantaneous indication of the relative phase between the local clock (CLK1 ) and the clock from the other board (CLK2 ). In terms of HDL, the flop-flop is provided by the next logic block.

The integrator logic integrates the relative phase using a counter over a period, in this example 125 us, at which time a decision is made to increase or decrease the delay of the local clock path. If the local board is the main/active/master (MAIN) card, then it slowly adjusts each delay lines to its midpoint. If the local board is the back-up/stand-by/slave card, then it adjusts its delay lines to keep CLK1 (rising edge) synchronized to CLK 2.

In the state machine, the fundamental phase step is set to a fine delay adjustment of 250 ps to the output of the stratum module. Fine adjustments are set here to occur no earlier than a predetermined time, such as 200 ms, after the previous fine adjustment. When the fine delay value approaches its maximum or minimum value, an appropriate coarse delay adjustment is made. The coarse delay adjustment (which may be made to the input of the stratum module) eventually propagates through the stratum module and (generally) moves the fine delay line away from its threshold. Coarse adjustments are set here not to occur no earlier than a predetermined time, such as 400 ms, after the previous coarse adjustment.

Although the present invention has been described with reference to particular arrangements and parameter values, it shall be appreciated that the exemplary embodiment may be modified or rearranged without deviating from the spirit and scope of the invention.

An APPENDIX is provided that sets forth a specific hardware description language (HDL) program according to on embodiment of the present invention.

[image]

[image]

[image]

[image]

[image]

[image]

1. An apparatus for minimizing a phase difference between frequency aligned clocks output from respective active and back-up clocks, wherein the active clock and the back-up clock are frequency aligned and out of phase, comprising:
a first electronic delay line for delaying a frequency reference input to one of said clocks;
a second electronic delay line for delaying an output of the one of said clocks;
a phase detector for detecting a phase difference between the active clock and the back-up clock; and
a controller for adjusting the first and second delay lines such that the phase offset between the clocks is minimized.

2. The apparatus according to claim 1, wherein the active clock includes a phase-locked loop (PLL) situated between the first and second electronic delay lines for frequency locking to the reference clock.

3. The apparatus according to 1, wherein the phase detector has a timing that is driven by the other of the one of said clocks.

4. The apparatus according to 1, wherein the phase detector includes at least a flip-flop.

5. The apparatus according to 4, wherein a clock pin of the flip-flop is driven by the back-up clock.

6. The apparatus according to 5, wherein a data pin of the flip-flop is driven by a clock from a main clock.

7. The apparatus according to 5, wherein an output of the flip-flop is a signal that indicates a lateness of the back-up clock.

8. The apparatus according to claim 1, wherein the output of the flip-flop indicates lateness when the active clock is already high when the flip-flop is clocked by a rising edge of the back-up clock.

9. The apparatus according to claim 1, further comprising a metastable filter for filtering metastability from the output of the flip-flop.

10. The apparatus according to claim 1, further comprising an integrator, to determine an amount of lateness observed over a period of time.

11. The apparatus according to claim 1, wherein the first electronic delay line is a coarse delay line that delays the input reference clock by coarse increments and the second delay line is a fine delay line that delays the output reference clock by substantially finer increments than the coarse delay line.

12. A method for minimizing a phase difference between frequency aligned clocks output from respective active and back-up clocks, wherein the active clock and the back-up clock are frequency aligned and out of phase, comprising the steps of:
delaying a reference clock of the active clock by coarse increments;
delaying an output of the active clock by fine increments that are substantially finer than the coarse increments;
controlling the delaying of the output of the active clock by fine increments when the output of the active clock reaches a predetermined threshold value by adjusting the delaying of the reference clock by coarse increments in a direction of the predetermined threshold that is reached;
controlling the delaying of the reference clock of the active clock by coarse increments when the reference clock reaches another predetermined threshold by incrementing the delaying of the reference clock by coarse increments in a direction of the another predetermined threshold.

13. The method of claim 12, further comprising the step of comparing a lateness between the back-up clock and the active clock indicating whether the back-up clock is one of earlier, in-phase, and later than the active clock.

14. The method of claim 13, further comprising the step of delaying the back-up clock more when the amount of lateness meets a predetermined lower threshold and a predetermined upper threshold is not met indicating that the back-up clock is earlier than the active clock.

15. The method of claim 13, further comprising the step of advancing the back-up clock when the lateness meets lower and upper thresholds indicating that the back-up clock is later.

16. The method of claim 13, further comprising the step of maintaining the back-up clock at a current phase when the amount of lateness meets a lower threshold but not an upper threshold indicating that the back-up clock is in phase with the active clock.

17. The method of claim 12, wherein the step of delaying the output of the active clock is incremented by a fine delay of substantially less than 0.01 unit interval (UI).

18. The method of claim 12, wherein the step of delaying the reference clock is incremented by a coarse delay line by greater than substantially 0.01 unit interval (UI).
